(19) United States
(12) Patent Application Publication
(10) Pub. No.: US 2007/0064175 A1
(43) Pub. Date: Mar. 22, 2007

(54) Nonvolatile polymer bistability memory device using nano particles that are formed in polymer thin film and method of manufacturing the nonvolatile polymer bistability memory device

(76) Inventors: Tae-whan Kim, Seoul (KR); Young-ho Kim, Seoul (KR); Jae-ho Kim, Seoul (KR); Jea-hun Jung, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/521,394

(22) Filed: Sep. 15, 2006

(30) Foreign Application Priority Data
Sep. 15, 2005 (KR) 10-2005-0086530

(51) Int. Cl. G02F 1/1333

(52) U.S. Cl. 349/86

(57) ABSTRACT

A nonvolatile polymer bistability memory device using nano particles that are formed in a polymer thin film and a method of manufacturing the nonvolatile polymer bistability memory device are provided. The nonvolatile polymer bistability memory device includes a semiconductor substrate, a first electrode on the semiconductor substrate, a polymer thin film on the first electrode, nano particles embedded into the polymer thin film, and a second electrode on the polymer thin film. The nonvolatile polymer bistability memory device does not need any source and drain to operate, and the method of manufacturing the nonvolatile polymer bistability memory device can guarantee high production efficiencies while maintaining low manufacturing costs.

### BACKGROUND OF THE INVENTION

1. Field of the Invention

The present invention relates to a semiconductor memory device, and more particularly, to a nonvolatile polymer bistability memory device using nano particles embedded in a polymer thin film, and a method of manufacturing the nonvolatile polymer bistability memory device.

This application claims priority from Korean Patent Application No. 10-2005-0086530 filed on Sep. 15, 2005 in the Korean Intellectual Property Office, the disclosure of which is incorporated herein by reference in its entirety.

2. Description of the Related Art

Nonvolatile memory devices do not lose data stored therein even when power supply is interrupted. Flash memory devices, which are one of the most representative nonvolatile memory devices, comprise a plurality of unit cells, each unit cell having an electrically isolated floating gate. Data stored in each unit cell of a flash memory device may be classified into data having a logic value of “1” or data having a logic value of “0” according to whether electric charges are present in the floating gate of the corresponding unit cell. A conventional flash memory device necessarily requires a source and a drain to operate. Accordingly, the manufacturing process of the conventional flash memory device is difficult and complicated.

As part of effort to develop memory devices that do not need any source and drain, organic electric bistability devices using metallic thin films that are formed in conductive organic monomers between metallic electrodes have been suggested. Such devices are manufactured by inserting a conductive organic monomer layer such as Alq3 or AIDCN between metallic electrodes and can thus be programmed according to electric charges present in a metallic thin film that is inserted into the conductive organic monomer layer. However, since conductive organic monomers are highly sensitive to moisture and heat, memory devices using conductive organic monomers must be manufactured in a pure condition. In other words, organic monomers can be easily degraded according to the external environment. Thus, in order to address this problem, additional processes of forming passivation layers are needed. Accordingly, the efficiency of manufacture of memory devices using organic monomers decreases, while the manufacturing costs of such memory devices increases.

Therefore, it is necessary to develop memory devices that do not need any source and drain to operate and methods of manufacturing such memory devices which can guarantee high production efficiencies while maintaining low manufacturing costs.

### SUMMARY OF THE INVENTION

According to an aspect of the present invention, there is provided a nonvolatile polymer bistability memory device using nano particles that are formed in a polymer thin film. The nonvolatile polymer bistability memory device comprises a semiconductor substrate, a first electrode on the semiconductor substrate, a polymer thin film on the first electrode, nano particles embedded into the polymer thin film, and a second electrode on the polymer thin film.

Here, the polymer thin film may comprise polyimide.

Also, the nano particles may comprises Cu2O.

In addition, the first and second electrodes may intersect each other.

Here, the first and second electrodes may comprises aluminum (Al) or copper (Cu).

According to another aspect of the present invention, there is provided a method of manufacturing nonvolatile polymer bistability memory device using nano particles that are formed in a polymer thin film, including forming a first electrode on a semiconductor substrate, forming a polymer thin film with embedded nano particles on the first electrode, and forming a second electrode on the polymer thin film.

Here, the forming of the polymer thin film may include forming a first polymer thin film on the first electrode, depositing a material layer on the first polymer thin film, the material layer being capable of producing the nano particles, forming a second polymer thin film on the material layer, and performing a hardening operation on the first polymer thin film, the material layer, and the second polymer thin film to form the polymer thin film with embedded nano particles.

Here, the forming of the first and second electrodes may further include performing a hardening operation by applying heat to the first polymer thin film, the material layer, and the second polymer thin film at a temperature of 350° C. for two hours.

Here, the first and second polymer thin films may be formed by spin coating.

The polymer thin film may comprises polyimide.

The nano particles may comprises Cu2O.

In forming a second electrode on the polymer thin film comprises forming a second electrode to intersect the first electrode.

Here, the first and second electrodes may comprises aluminum (Al) or copper (Cu).

### BRIEF DESCRIPTION OF THE DRAWINGS

The above and other features and advantages of the present invention will become more apparent by describing in detail preferred embodiments thereof with reference to the attached drawings in which:

FIG. 1 is a perspective view of a nonvolatile polymer bistability memory device using nano particles that are formed in a polymer thin film, according to an exemplary embodiment of the present invention;

FIG. 2 is a plan view of the nonvolatile polymer bistability memory device illustrated in FIG. 1;

FIG. 3 is a cross-sectional view of the nonvolatile polymer bistability memory device illustrated in FIG. 1;

FIG. 4 is a plan bright field image of nano particles formed in a polymer thin film of a nonvolatile polymer bistability memory device according to the exemplary embodiment of the present invention;

FIG. 5 is a cross-sectional dark field image of nano particles formed in a polymer thin film of a nonvolatile polymer bistability memory device according to the exemplary embodiment of the present invention;

FIG. 6 is an electric diffraction pattern of nano particles formed in a polymer thin film of a nonvolatile polymer bistability memory device according to the exemplary embodiment of the present invention;

FIG. 7 is a flowchart illustrating a method of manufacturing a nonvolatile polymer bistability memory device using nano particles that are formed in a polymer thin film, according to the exemplary embodiment of the present invention;

FIG. 8 is a graph presenting voltage versus current measurement results regarding a write operation, a read operation, and an erase operation performed on a nonvolatile polymer bistability memory device using nano particles that are formed in a polymer thin film, according to the exemplary embodiment of the present invention;

FIG. 9 is an energy band diagram of a nonvolatile polymer bistability memory device according to an exemplary embodiment of the present invention when no voltage is applied thereto;

FIG. 10 is an energy band diagram of a nonvolatile polymer bistability memory device according to the exemplary embodiment of the present invention when a write voltage is applied thereto;

FIG. 11 is an energy band diagram of a nonvolatile polymer bistability memory device according to the exemplary embodiment of the present invention when a read voltage is applied thereto; and

FIGS. 12 and 13 are energy band diagrams of a nonvolatile polymer bistability memory device according to the exemplary embodiment of the present invention when an erase voltage is applied thereto.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

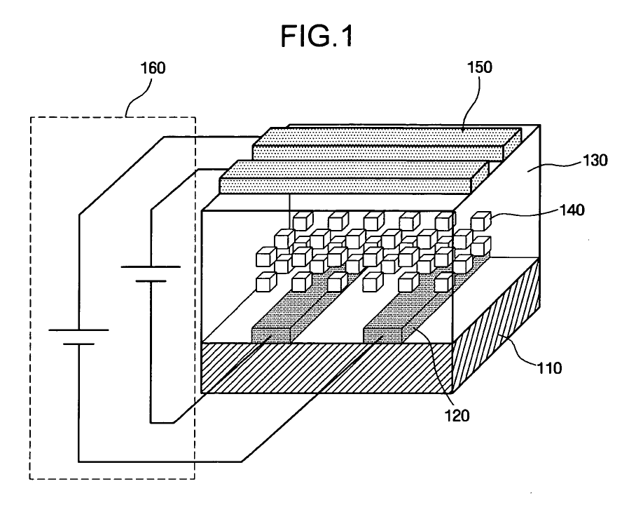

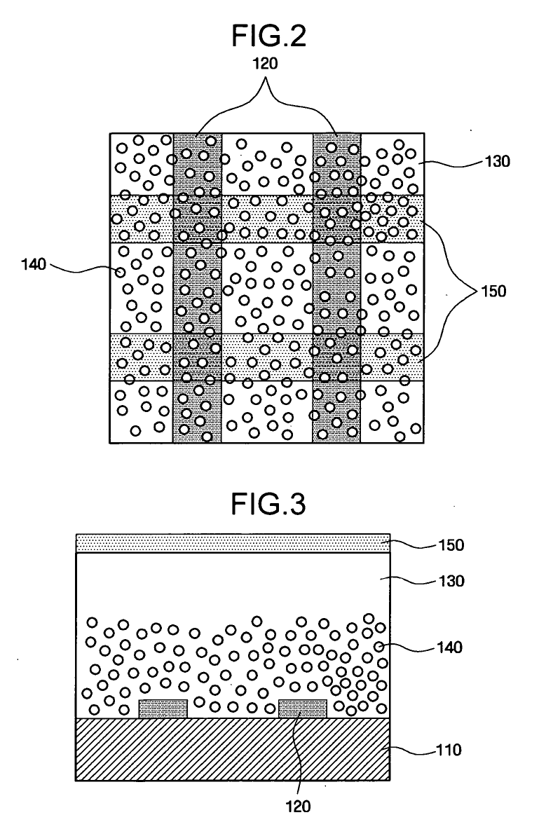

FIG. 1 is a perspective view of a nonvolatile polymer bistability memory device using nano particles that are formed in a polymer thin film, according to an exemplary embodiment of the present invention, FIG. 2 is a plan view of the nonvolatile polymer bistability memory device illustrated in FIG. 1, and FIG. 3 is a cross-sectional view of the nonvolatile polymer bistability memory device illustrated in FIG. 1. Referring to FIGS. 1 through 3, a nonvolatile polymer bistability memory device according to an embodiment of the present invention includes a semiconductor substrate 110, first electrodes 120, a polymer thin film 130, nano particles 140, and second electrodes 150. The first electrodes 120 and the second electrodes 150 are connected to a driving circuit 160.

The semiconductor substrate 110 may be a typical semiconductor substrate such as a silicon (Si) substrate. The first and second electrodes 120 and 150 receive an electric signal transmitted by the driving circuit 160 so that the polymer thin film 130 and the nano particles 140 can be charged or discharged. Referring to FIG. 1, the first electrodes 120 are connected to a cathode of the driving circuit 160, and the second electrodes 150 are connected to an anode of the driving circuit 160. The first electrodes 120 and/or the second electrodes 150 may be formed of copper (Cu) or aluminum (Al). Each of the first and second electrodes 120 and 150 may be formed as a bar that extends in a predetermined direction or a plate that covers an upper or lower surface of the polymer thin film 130. In a case where the first and second electrodes 120 and 150 are formed as bars, the first and second electrodes 120 and 150 may intersect each other. By forming the first and second electrodes 120 and 150 to intersect each other, it is possible to increase the efficiency of a write/read/erase operation performed on the nonvolatile polymer bistability memory device, and to simplify the peripheral circuitry layout in integration of semiconductor devices.

The polymer thin film 130 may be formed of biphenyltetracarboxylic dianhydride-p-phenylenediamine (BPDA-PDA) polyamic acid. The polymer thin film 130 electrically insulates the first electrodes 120 from the second electrodes 150, and causes Fowler-Nordheim tunneling when a uniform voltage is generated. According to the present embodiment, the polymer thin film 130 may be formed to a thickness of 40 nm. The thicker the polymer thin film 130 is, the lower the leakage current becomes and the longer the polymer thin film 130 can hold electrons captured by nano particles. However, the thicker the polymer thin film 130 is, the higher the external voltage becomes and the higher the entire operating voltage becomes. Therefore, the thickness of the polymer thin film 130 may be determined in consideration of all the factors mentioned above. Accordingly, electrons can move from the cathode to the anode of the driving circuit 160 by tunneling through a dielectric material, i.e., the polymer thin film 130.

Tunneling is a phenomenon in which particles with low energy become able to tunnel through an energy barrier due to the quantum effect as the thickness of the energy barrier decreases. Tunneling cannot be explained by classical mechanics but can only be explained by quantum mechanics. Tunneling is classified into either direct tunneling or Fowler-Nordheim tunneling. Direct tunneling occurs when an energy barrier is rectangular (i.e., when an external electric field is weak). Fowler-Nordheim tunneling occurs when the shape of an energy barrier changes from a rectangle to a triangle as an external electric field becomes strong. When the shape of an energy barrier changes, the same effect of reducing the thickness of the energy barrier can be offered to particles, even though the thickness of the energy barrier has not changed. Accordingly, in a given electric field, a current generated by Fowler-Nordheim tunneling is higher than a current generated by direct tunneling. In general, Fowler-Nordheim tunneling and direct tunneling both occur in a device. In other words, when an external electric field is weak, particles are injected by direct tunneling, and as the external electric field becomes strong, particles are injected by Fowler-Nordheim tunneling.

With the ever-growing demand for the development of new materials that can replace silicon dioxide (SiO2), which is one of the most widely used dielectric materials, polyimide, which is an organic dielectric material, has gained acceptance as a replacement of conventional inorganic dielectric materials. Polyimide has been widely used in various fields of the precision electronic industry, including the field of interlayer dielectric layers for integrated circuits and the field of high-density interconnect packages, due to its unique thermal, mechanical, and dielectric properties. It is well known that polyimide has a lower dielectric constant than conventional inorganic dielectric materials.

The nano particles 140 may be formed of a metallic oxide such as Cu2O or ZnO. However, the present invention is not restricted to this. Any material (e.g., Cu, Zn, Sn, NiFe, Ag, and etc.) capable of producing nano particles when polyamic acid is heat treated while employing the processes such as spin coating or heat treatment according to the exemplary embodiments of the present invention may be used. A method of spontaneously generating the nano particles 140 in the polymer thin film 130 is as follows. First, a polyamic acid layer is formed by spin-coating BPDA-PDA polyamic acid in N-methyl-2-pyrrolidone solvent on the first electrodes 120. In order to remove the solvent, heat may be applied to the polyamic acid layer at a temperature of 135° C. for thirty minutes. Thereafter, a Cu or Zn layer may be deposited on the polyamic acid layer to a thickness of 5 nm. Thereafter, polyamic acid may be spin-coated again on the Cu or Zn layer, and then the resultant may be preserved at room temperature for twenty four hours. Thereafter, a hardening operation is performed by applying heat at a temperature of 350° C. for two hours to form the polymer thin film 130 (e.g., a polyimide thin film) with a high density of Cu2O or ZnO nano particles uniformly distributed therein.

The size and density of the nano particles 140 can be determined according to the type of metal used for producing the nano particles 140, the initial thickness of the polymer thin film 130, the mixing ratio of a solvent and a BPDA-PDA precursor, and the hardening operation conditions. In general, the size of the nano particles 140 can be determined according to heat treatment time. The shorter the heat treatment time is, the smaller the nano particles 140 become. On the contrary, the longer the heat treatment time is, the larger the nano particles 140 become. As the heat treatment time increases, the density of the nano particles 140 generally increases. Also, as the amount of initial deposition of Cu or Zn increases, the density of the nano particles 140 increases.

By adjusting the size and density of the nano particles 140, it is possible to appropriately adjust the amount of time for which the nano particles 140 can hold electric charges according to the magnitude of an externally applied voltage. The longer the nano particles 140 can hold electric charges, the better the characteristics of the nonvolatile polymer bistability memory device become. Even though the increase in the amount of time for which the nano particles 140 can hold electric charges is explained by more than just one factor, it is safe to say that the larger the nano particles 140 are, the longer the nano particles 140 can hold electric charges.

Therefore, the present invention provides a nonvolatile polymer bistability memory device employing metallic nano particles that are formed in a polymer dielectric layer by spin coating and hardening operations and can thus enable capture and discharge electric charges. Since the nano particles 140 is relatively uniformly embedded in the polymer thin film 130 and rarely cohere, the number of electric charges that are captured and discharged by the nano particles 140 can be adjusted by adjusting the size and density of the nano particles 140. In this manner, a nonvolatile polymer bistability memory device may be manufactured in a customizable manner, for example, in a voltage application area, which is an area requested by a device user. A nonvolatile polymer bistability memory device according to the exemplary embodiment of the present invention is less costly and easier than a conventional nonvolatile memory device to manufacture because of the use of nano particles that are electrically and chemically stable. The polymer thin film 130 may be formed of various materials. Hereinafter, structural characteristics and electric operations of a nonvolatile polymer bistability memory device with a polyimide layer as the polymer thin film 130 is explained.

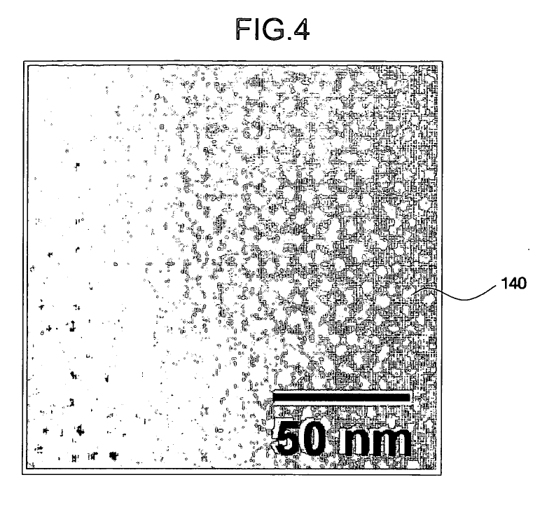

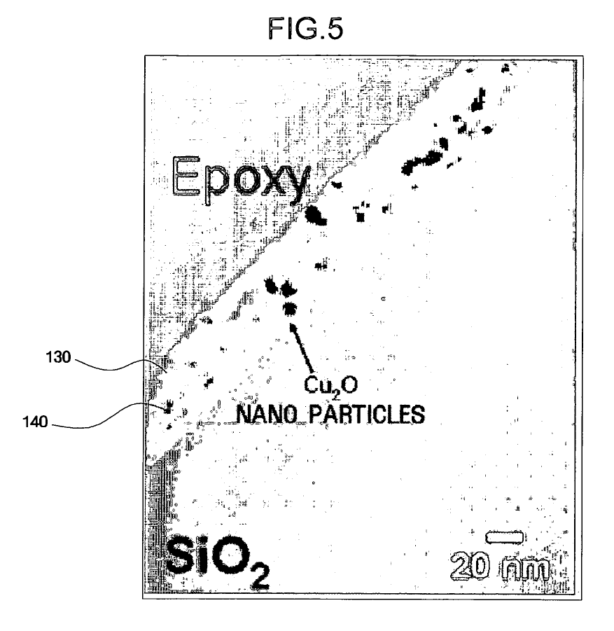

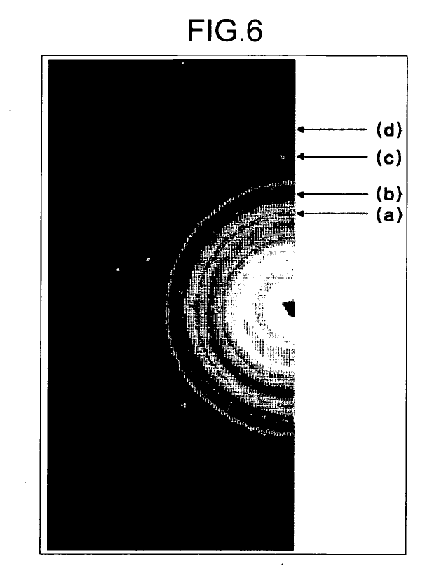

FIG. 4 is a plan bright field image of nano particles formed in a polymer thin film of a nonvolatile polymer bistability memory device according to the exemplary embodiment of the present invention, FIG. 5 is a cross-sectional dark field image of nano particles formed in a polymer thin film of a nonvolatile polymer bistability memory device according to the exemplary embodiment of the present invention, and FIG. 6 is a electric diffraction pattern of nano particles formed in a polymer thin film of a nonvolatile polymer bistability memory device according to the exemplary embodiment of the present invention.

Referring to FIG. 4, about six to eight nano particles are relatively uniformly distributed along a 50 nm-long straight line. FIG. 5 illustrates a uniform distribution of the nano particles 140 embedded in the polymer thin film 130, which is formed on the SiO2 layer, and epoxy resin that protects the polymer thin film 130. The nano particles 140 are relatively uniformly distributed-in the polymer thin film 130. FIG. 6 presents an electric diffraction pattern formed by the nano particles 140 which are uniformly distributed in the polymer thin film 130. Referring to FIG. 6, the nano particles 140 are face-centered cubic, and diffraction rings appear because the size of the nano particles 140 is small. In general, a diffraction pattern of a material displays a crystallographic direction indicated by each diffraction ring, and the crystalline structure of the material can be determined by interpreting the crystallographic direction. The clearer each diffraction ring displayed in a diffraction pattern of a material is, the more likely the material is to be monocrystallized. Referring to FIG. 6, since polyimide does not have a repetitive crystalline structure, a diffraction pattern of polyimide lacks distinction. On the other hand, since Cu2O has a crystalline structure, diffraction rings corresponding to Cu2O appear in a diffraction pattern of Cu2O. The diffraction rings corresponding to Cu2O are unclear because the number of Cu2O nano particles is small and the Cu2O nano particles are not uniformly distributed in polyimide.

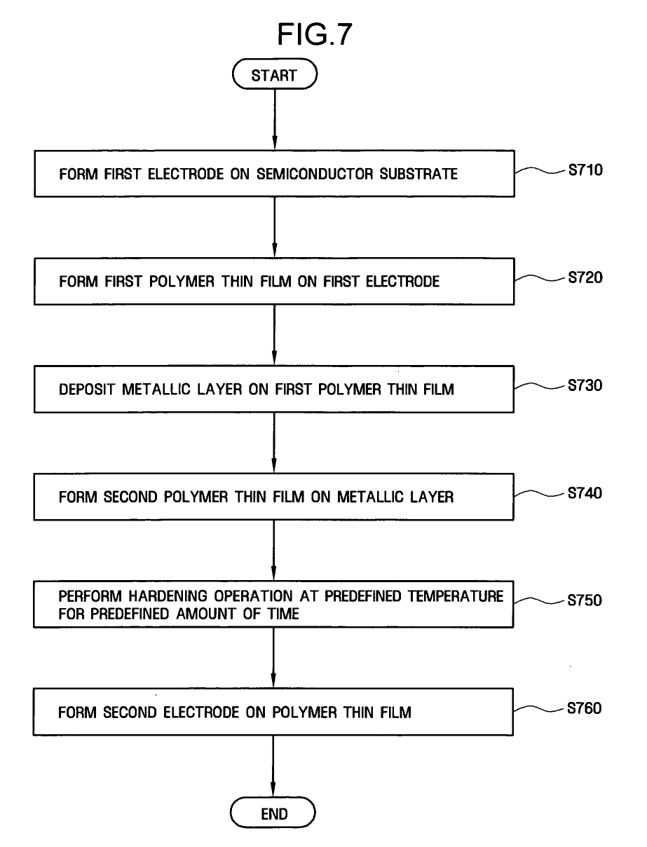

FIG. 7 is a flowchart illustrating a method of manufacturing a nonvolatile polymer bistability memory device using nano particles that are formed in a polymer thin film, according to an exemplary embodiment of the present invention. Referring to FIG. 7, in operation S710, a first electrode 120 is formed on a semiconductor substrate 110. The first electrode 120 may be formed in various shapes. For example, the first electrode 120 may be formed of Cu or Al as a bar that extends in a predetermined direction or a plate that covers an entire surface of the semiconductor substrate 110.

In operation S720, a first polymer thin film is deposited or formed on the first electrode 120. The first polymer thin film may be formed of BPDA-PDA polyamic acid using N-methyl-2-pyrrolidone as a solvent. In order to remove the solvent, heat may be applied to the first polymer thin film at a temperature of 135° C. for thirty minutes. Also, the first polymer thin film may be formed on the first electrode 120 by performing spin coating. Spin coating may be performed by a spin coating apparatus. The spin coating apparatus applies a coating liquid onto the surface of a substrate, and spins a spin chuck to which the substrate is attached at high speed, thereby forming a coating layer on the substrate to a uniform thickness. From the viewpoint of the necessity of accurately forming a coating layer having a desirable thickness, a spin coating method is generally efficient compared to a deeping method, a spraying method, or a rolling method.

In order to form a coating layer having a predetermined thickness, several parameters need to be appropriately adjusted. Of the several parameters, the viscosity of a coating liquid and a final spin speed are deemed to be most important. Typical photoresist has a thickness of 0.6 to several micrometers may be formed at a spin speed of 100-1500 rpm. When determining the spin speed, consideration is also to be taken into the lifetime of a device because a spinner motor is highly likely to be damaged at speeds higher than 1000 rpm. Thus, spin speed is an important process parameter that needs to be well managed.

The spin coating apparatus may include a cover and a case that is coupled to the cover. A vacuum spin chuck to which a substrate is attached, a spin axial member which is coupled to the vacuum spin chuck, and a spin motor which spins the spin axial member may be installed inside the cover. An internal cover and a rectifying plate are installed above the substrate. A through hole is formed at a predetermined location on the cover so that air can flow into the spin coating apparatus through the through hole. An air adjustment unit is coupled to the through hole by a screw and adjusts the amount of air that flows into the spin coating apparatus through the through hole. A plurality of exhaust holes and a plurality of exhaust ducts are formed under the case so that a coating liquid and air that flow into the spin coating apparatus can be discharged. Also, a tray unit is installed near the substrate. The tray unit includes a tray and a tray cover which is coupled to the tray.

A method of coating a coating liquid on a substrate using the spin coating apparatus will hereinafter be described in detail. First, a coating liquid is applied onto a substrate using a dispenser (not shown). When the spin axial member of the spin coating apparatus is spun by applying power to the spin motor, the vacuum spin chuck may also be spun along with the spin axial member.

When the vacuum spin chuck is spun, the substrate is spun along with the vacuum spin chuck. Then, the coating liquid is dispersed due to a centrifugal force and is thus coated on the entire surface of the substrate. Waste fluid that still remains inside the case after the coating of the substrate is discharged through a retrieval hole of a retrieval unit which is formed at the tray. Alternatively, an aqueous solution may be sprayed through the exhaust holes beneath the case in order to prevent the remainder of the coating liquid from being solidified. The present invention, however, is not restricted to the aforementioned spin coating method.

In operation S730, a metallic layer is deposited or formed on the first polymer thin film. A metal used for forming the metallic layer produces nano particles 140 after being treated by subsequent processes. The thickness of the metallic layer may be determined according to the target thickness of final polymer thin film (130 in FIG. 1), the type of metal used to form the nano particles 140, the mixing ratio of a solvent and a BPDA-PDA precursor, and conditions under which a hardening operation is to be performed. Preferably, the thickness of the metallic layer may be 5 nm.

In operation S740, a second polymer thin film is formed on the metallic layer. The second polymer thin film may be formed of the same material as the first polymer thin film, and the first and second polymer thin films may be integrated into a single polymer thin film by subsequent processes. The second polymer thin film may be preserved at room temperature for twenty four hours. The generation of the nano particles 140 can be facilitated by preserving a resultant having second and first polymer thin films with the metallic layer sandwiched therebetween at room temperature for twenty four hours, rather than by readily applying heat to the resultant at a temperature of 135° C. Since even a slightest failure in the setting of conditions for subsequent heat treatment processes may lead to a complete failure in the generation of the nano particles 140, the preservation of the resultant at room temperature for twenty four hours is meaningful in terms of ensuring the generation of the nano particles 140.

In operation S750, a hardening operation is performed on the resultant at a predefined temperature for a predefined amount of time. The hardening operation may be performed by continuously applying heat at a temperature of 350° C. for two hours. As a result of the hardening operation, a high density of Cu2O nano particles can be formed and uniformly distributed in a polyimide thin film.

In operation S760, a second electrode 150 is formed on the second polymer thin film. The second electrode 150 may be formed of Cu or Al. Also, the second electrode 150, like the first electrode 120, may be formed as a bar that extends in a predetermined direction or a plate that covers an entire upper surface of polymer thin film 130. When the first and second electrodes 120 and 150 are formed as bars, the first and second electrodes 120 and 150 may intersect each other.

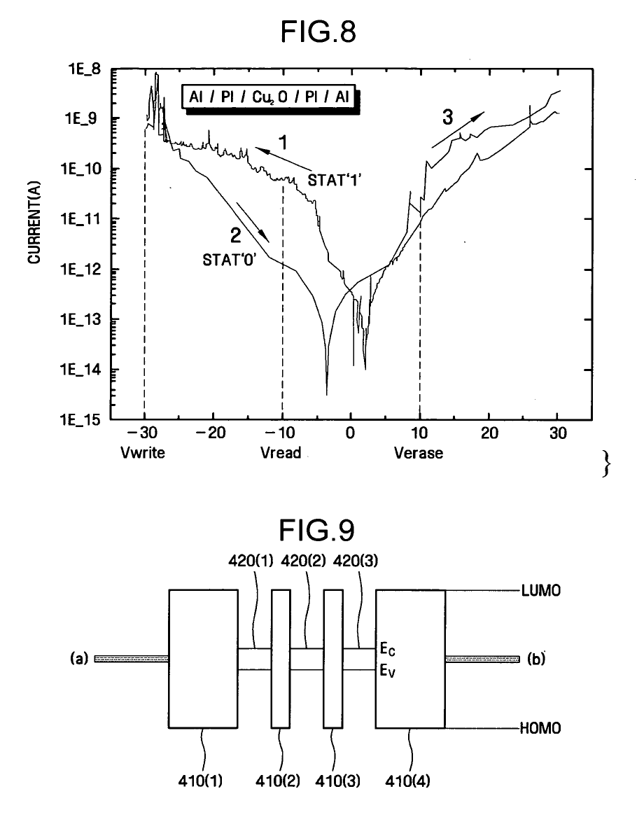

Electrical operation of a nonvolatile polymer bistability memory device employing nano particles embedded in a polymer thin film will hereinafter be described in further detail with reference to FIGS. 8 through 13.

FIG. 8 is a graph presenting voltage versus current measurement results regarding a write operation, a read operation, and an erase operation performed on a nonvolatile polymer bistability memory device using nano particles that are formed in a polymer thin film, according to the exemplary embodiment of the present invention. Referring to FIG. 8, the nonvolatile polymer bistability memory device includes an Al electrode, a polyimide layer (Pl), Cu2O nano particles, a polyimide layer, and an Al electrode which are sequentially arranged from the top to the bottom of the nonvolatile polymer bistability memory device. Referring to FIG. 8, a voltage versus current relationship when an applied voltage is changed from 30 V to −30 V is indicated by a solid line, and a voltage versus current relationship when the applied voltage is changed from −30 V to 30 V is indicated by a dotted line. Hereinafter, the situation when the applied voltage is changed from 0 V to −30 V will be referred to as process 1, the situation when the applied voltage is changed from −30 V to 0 V will be referred to as process 2, and the situation when the applied voltage is changed from 0 V to 30 V will be referred to as process 3. Assume that a write voltage Vwrite, a read voltage Vread, and an erase voltage Verase are respectively −30 V, −10 V, and 10 V. Referring to FIG. 8, state 1 indicates the intersection point between the read voltage Vread and the solid line, and state 0 indicates the intersection point between the read voltage Vread and the dotted line. Processes 1 through 3 and states 0 and 1 will hereinafter be described in further detail.

FIG. 9 is an energy band diagram of a nonvolatile polymer bistability memory device according to an exemplary embodiment of the present invention when no voltage is applied thereto. Referring to FIG. 9, the nonvolatile polymer bistability memory device includes a polymer thin film (410(1), 410(2), 410(3), and 410(4)), nano particles (420(1), 420(2), and 420(3)), and a pair of electrodes ((a) and (b)). Referring to FIG. 9, LUMO indicates a lowest energy level corresponding to a molecular orbital without electron of a dielectric polymer, HOMO indicates a highest energy level corresponding to molecular orbital with electron of the dielectric polymer, Ec indicates a lowest energy level of a conduction band of a compound semiconductor (i.e., a nano particle), and Ev indicates a highest energy level of the conduction band of the compound semiconductor. The nano particles (420(1), 420(2), and 420(3)) are relatively uniformly distributed in the polymer thin film (410(1), 410(2), 410(3), and 410(4)). FIG. 9 illustrates an energy band of the nonvolatile polymer bistability memory device when an external voltage is not applied to the electrodes (a) and (b).

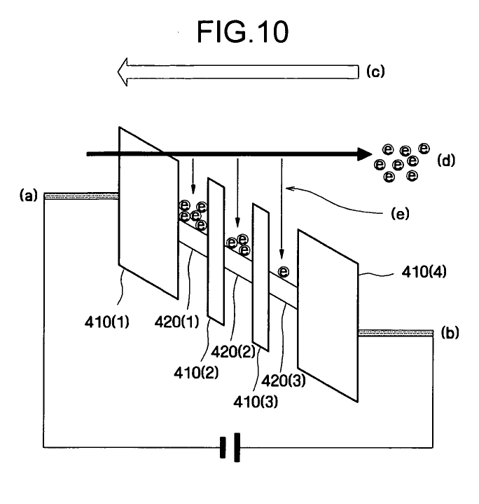

FIG. 10 is an energy band diagram of a nonvolatile polymer bistability memory device according to the exemplary embodiment of the present invention when a write voltage Vwrite is applied thereto. The energy band diagram illustrated in FIG. 10 is based on the energy of electrons. In general, when a negative voltage is applied to a device, electrons are injected from a cathode of the device, and the energy of the cathode is high. Eventhough, FIG. 10 is illustrated as a large quantity of electrons are near an anode, it should be interpreted that the electrons have actually absorbed by the anode rather than have been gathered near the anode.

When an external voltage (i.e., the voltage Vwrite) is applied so that the electrodes (a) and (b) can be respectively connected to the cathode and the anode, an external electric field (c) is generated in a direction from the right to the left. By applying write voltage Vwrite (refer to “process 1”), electrons are injected from the cathode, i.e., the electrode (a) to the anode, i.e., the electrode (b) , by Fowler-Nordheim-tunneling through a polyimide layer, as indicated by (d). Most of the electrons that are injected from the cathode are abosorbed into the anode, i.e., the electrode (b), along the external electric field (c), and the remaining electrons are captured by compound semiconductor nano particles(420(1), 420(2), and 420(3)) that are spontaneously generated in the polymer thin film, i.e., a polyimide layer, as indicated by (e). Most of the captured electrons are located near the cathode, i.e., the electrode (a), and the number of electrons that are captured decreases closer to the anode, i.e., the electrode (b). In this case, even if the external voltage is removed, electrons can be maintained to be captured by the nano particles because the polyimide layer serves as a dielectric material, thereby realizing a state that enables storage of information.

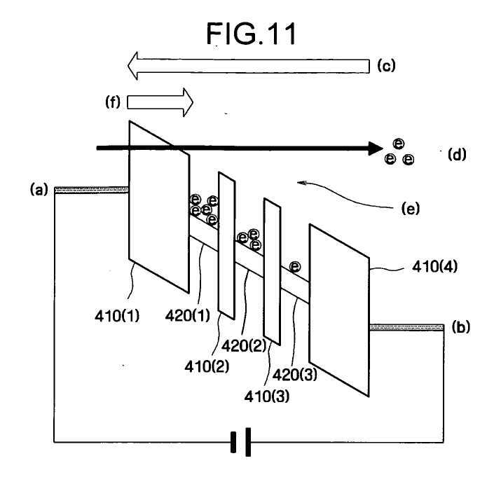

FIG. 11 is an energy band diagram of a nonvolatile polymer bistability memory device according to the exemplary embodiment of the present invention when a read voltage Vread (refer to “process 1” or “process 2”) is applied thereto. It is determined whether a current state is state 1 or state 0 according to whether electrons are captured by compound semiconductor nano particles in a polyimide layer and the pattern of distribution of the electrons in the polyimide layer.

State 0

Referring to FIG. 11, when the read voltage Vread is applied according to process 2, electrons are captured by compound semiconductor nano particles. Since most of the captured electrons are located near the surface of the cathode, i.e., the electrode (a), an internal electric field (f) whose direction is opposite to the direction of the external electric field (c) is generated. Accordingly, an electric field that affects part of the polyimide layer near the cathode, i.e., the electrode (a), becomes weak, thereby reducing the electron injection efficiency of Fowler-Nordheim tunneling. Therefore, a current generated when the read voltage Vread is applied is lower in state 0 than in state 1.

State 1

When the read voltage Vread is applied according to process 1, few electrons are captured by compound semiconductor nano particles that are located near the surface of the cathode since V read does not reach the write voltage Vwrite. Accordingly, the internal electric field (f) that interferes with the external electric field (c) is not generated, and thus, the electron injection efficiency of Fowler-Nordheim tunneling does not decrease. Therefore, a current generated when the read voltage Vread is applied is higher in state 1 than in state 0. Since a current generated in state 1 is about 100 times higher than a current generated in state 0, it is possible to identify data stored in the nonvolatile polymer bistability memory device by measuring the difference between the current generated in state 1 and the current generated in state 0 with the aid of a driving circuit. State 1 has been described above as corresponding to a high current, and state 0 has been described above as corresponding to a low current. However, the present invention is not restricted to this.

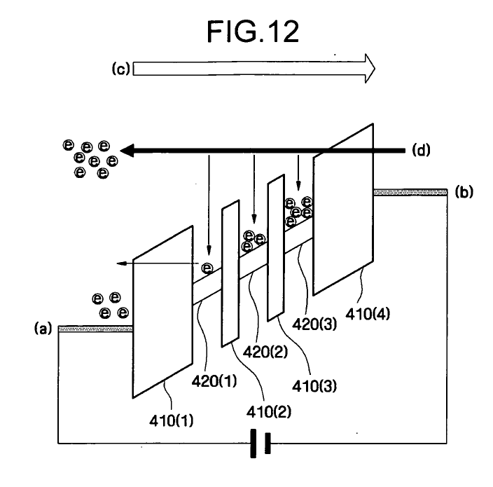

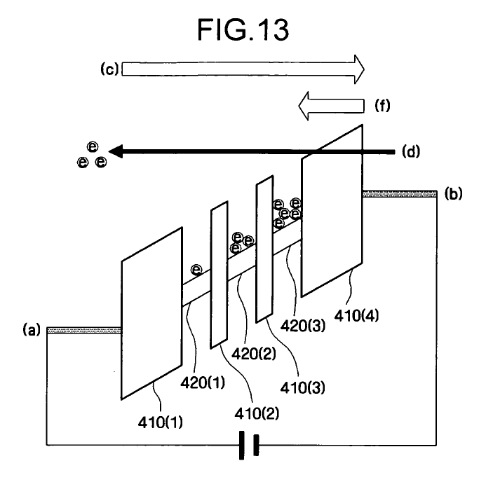

FIGS. 12 and 13 are energy band diagrams of a nonvolatile polymer bistability memory device according to the exemplary embodiment of the present invention when an erase voltage Verase is applied thereto. Referring to FIGS. 12 and 13, an external voltage, i.e., the erase voltage Verase, is applied so that the electrodes (a) and (b) can be respectively connected to the anode and the cathode.

Referring to FIG. 12, electrons injected from the cathode, i.e., the electrode (b) to the anode, i.e., the electrode (a) are captured by compound semiconductor nano particles that are located near the electrode (b), while compound semiconductor nano particles that are located near the anode, i.e., the electrode (a), discharge previously captured electrons to the electrode (a).

Referring to FIG. 13, the distribution of electrons in the polymer thin film after an erase operation is terminated is opposite to the distribution of electrons in the polymer thin film after a write operation is terminated as shown in FIG.10. Accordingly, electrons that are captured by compound semiconductor nano particles do not affect the efficiency of electron injection during a write operation, and thus, when an erase operation is terminated, the nonvolatile polymer bistability memory device can readily return to its initial state.

As described above, according to the exemplary embodiment of the present invention, no source and drain is needed to operate, and it is possible to guarantee high production efficiencies while maintaining low manufacturing costs.

In addition, according to the exemplary embodiment of the present invention, it is possible to simplify the manufacture of a nonvolatile polymer bistability memory device using the charge-trapping characteristics of nano particles that are spontaneously generated in a polymer thin film.

Moreover, according to the exemplary embodiment of the present invention, it is possible to offer a simpler method of manufacturing a memory device than a method of manufacturing a conventional flash memory device using polysilicon nano particles, and to provide a memory device that is electrically and chemically stable.

Although only a few exemplary embodiments of this invention have been described in detail above, those skilled in the art will readily appreciate that many modifications are possible in the exemplary embodiments within the spirit and scope of this invention. Therefore, it is to be understood by those of ordinary skill in the art that various changes in form and details may be made therein without departing from the spirit and scope of the present invention as defined by the following claims.

What is claimed is:

1. A nonvolatile polymer bistability memory device comprising:
a semiconductor substrate;
a first electrode on the semiconductor substrate;
a polymer thin film on the first electrode;
nano particles embedded into the polymer thin film; and
a second electrode on the polymer thin film.

2. The nonvolatile polymer bistability memory device of claim 1, wherein the polymer thin film comprises polyimide.

3. The nonvolatile polymer bistability memory device of claim 1, wherein the nano particles comprises Cu2O.

4. The nonvolatile polymer bistability memory device of claim 1, wherein the first and second electrodes intersect each other.

5. The nonvolatile polymer bistability memory device of claim 1, wherein the first and second electrodes comprises aluminum (Al) or copper (Cu).

6. A method of manufacturing nonvolatile polymer bistability memory device comprising:
forming a first electrode on a semiconductor substrate;
forming a polymer thin film on the first electrode with embedded nano particles; and
forming a second electrode on the polymer thin film.

7. The method of claim 6, wherein forming a polymer thin film on the first electrode with embedded nano particles comprises:
forming a first polymer thin film on the first electrode;
depositing a material layer on the first polymer thin film, the material layer being capable of producing the nano particles;
forming a second polymer thin film on the material layer; and
performing a hardening operation on the first polymer thin film, the material layer, and the second polymer thin film to form the polymer thin film with embedded nano particles.

8. The method of claim 7, wherein performing a hardening operation comprises applying heat to the first polymer thin film, the material layer, and the second polymer thin film at a temperature of 350° C. for two hours.

9. The method of claim 7, wherein forming a first and second polymer thin films are performed by spin coating.

10. The method of claim 6, wherein the polymer thin film comprises polyimide.

11. The method of claim 6, wherein the nano particles comprises Cu2O.

12. The method of claim 6, wherein forming a second electrode on the polymer thin film comprises forming a second electrode to intersect the first electrode.

13. The method of claim 6, wherein the first and second electrodes comprises aluminum (Al) or copper (Cu).
